(19) United States
(12) Patent Application Publication
(10) Pub. No.: US 2022/0324704 A1
(43) Pub. Date: Oct. 13, 2022

(54) SYSTEM AND METHOD FOR DESIGNING A SCANNING MIRROR ASSEMBLY WITH AN OPTIMIZED FREQUENCY BANDWIDTH BASED ON SPRING CONSTANT INFORMATION

(71) Applicant: BEIJING VOYAGER TECHNOLOGY CO., LTD., Beijing (CN)

(72) Inventors: Youmin Wang, Berkeley, CA (US); Yufeng Wang, Mountain View, CA (US); Qin Zhou, Mountain View, CA (US); Gary Li, Mountain View, CA (US)

(73) Assignee: BEIJING VOYAGER TECHNOLOGY CO., LTD., Beijing (CN)

(21) Appl. No.: 17/226,071

(22) Filed: Apr. 8, 2021

(51) Int. Cl. B81C 99/00; G01S 7/481; G02B 26/08

(52) U.S. Cl. CPC B81C 99/006; G01S 7/4817; G02B 26/0833

(57) ABSTRACT

Embodiments of the disclosure provide a method for designing an optical scanning mirror. The method may include receiving an initial set of design parameters for the scanning mirror assembly. The method may also include simulating first scanning mirror oscillation based on the initial set of design parameters to compute an initial non-linear spring constant associated with at least one spring of the scanning mirror assembly. The method may further include adjusting the set of design parameters for the scanning mirror assembly based on a comparison between the initial non-linear spring constant and a target non-linear spring constant. The method may also include outputting the at least one structural alteration to be implemented on the at least one spring. In certain aspects, the initial set of design parameters and the adjusted set of design parameters may be associated with a same mirror oscillation frequency and linear spring constant.

### TECHNICAL FIELD

The present disclosure relates to designing scanning mirrors used in optical sensing systems, and more particularly to, a method for designing a scanning mirror assembly with an optimized frequency bandwidth by generating linear and non-linear spring constant information using a computer model to simulate scanning mirror oscillation associated with a set of design parameters.

### BACKGROUND

Optical sensing systems, e.g., such as LiDAR systems, have been widely used in advanced navigation technologies, such as to aid autonomous driving or to generate high-definition maps. For example, a typical LiDAR system measures the distance to a target by illuminating the target with pulsed laser light beams and measuring the reflected pulses with a sensor. Differences in laser light return times, wavelengths, and/or phases can then be used to construct digital three-dimensional (3D) representations of the target. Because using a narrow laser beam as the incident light can map physical features with very high resolution, a LiDAR system is particularly suitable for applications such as sensing in autonomous driving and high-definition map surveys.

A LiDAR system may include a transmitter configured to emit a light beam to scan an object and a receiver configured to receive the light beam reflected by the object. The transmitter and the receiver may use optical components (e.g., a scanning mirror) to steer the light beam to a range of directions. A scanning mirror can be a single micro mirror, or an array of micro mirrors integrated into a micromachined mirror assembly made from semiconductor materials such as using microelectromechanical system (MEMS) technologies. In certain applications, a MEMS mirror may be operated at or near resonance. Using resonance may enable optical sensing systems to obtain large mirror scanning angles in a relatively small amount of time as compared to a non-resonating mirror. A MEMS mirror may resonate at or near its characteristic oscillation frequency, which may be determined by the design parameters associated with the scanning mirror, scanner, and/or transmitter.

These design parameters may include, e.g., mirror size, Q-factor, comb finger number, distance between comb fingers, length of comb fingers, drive frequency and amplitude, spring dimension, linear spring constant, non-linear spring constant, just to name a few. These design parameters can be adjusted during the design phase so that the scanning mirror meets one or more target performance characteristic(s), e.g., a target mirror scanning angle, a characteristic oscillation frequency, a target oscillation frequency bandwidth, etc.

The oscillation frequency bandwidth is a characteristic range of frequencies at which a scanning mirror assembly can be driven to oscillate around an axis of rotation. The characteristic range may include the characteristic oscillation frequency of the scanning mirror assembly itself and a set of frequencies located on either side of the characteristic oscillation frequency.

Various design parameters may affect the oscillation frequency bandwidth of a scanning mirror assembly. Examples of such design parameters include, among others, the linear spring constant k₁ and the non-linear spring constant k₃ associated with the torsion spring(s) included in the scanning mirror assembly. As will be demonstrated later, a ratio r₃=k₃/k₁ (also referred to as the “spring constant ratio”) of the non-linear spring constant k₃ over the linear spring constant k₁ controls the oscillation frequency bandwidth (also referred to as the “frequency response bandwidth”).

For example, the spring constant ratio r₃ is proportional to the oscillation frequency bandwidth such that the larger r₃, the wider the oscillation frequency bandwidth. Designing a scanning mirror assembly such that the set of design parameters maximize the associated oscillation frequency bandwidth while maintaining a desired characteristic oscillation frequency may be advantageous in terms of controlling the scanning mirror angle during use by adjusting the drive frequency in the accompanying scanner electronics. Hence, computing the spring constant ratio r₃ with a high degree of accuracy and efficiency during the design phase may be beneficial, particularly when designing a scanning mirror assembly with specific performance requirements.

For a rigid scanning mirror assembly, r₃ may be computed by finding solutions for Equation (1), which is the equation governing motion for a rigid body under a single degree of freedom:

$$J \frac{{\partial }^{2} θ}{\partial {t}^{2}} + d \frac{\partial θ}{\partial t} + k ( θ + {r}_{3} {θ}^{3} ) = {\sum }_{i = 1}^{N} f ( θ ) {L}_{i} {V}^{2} ( t ) \qquad ( 1 )$$

where θ is the angular displacement, J is mirror rotational moment of inertia, d is damping coefficient, k is rotational spring constant, N is number of drive comb unit, and f(θ) is electrostatic force from a single comb drive under a unit voltage as a function of angular displacement, Lᵢ is equivalent arm length of the comb drive relative to the axis of rotation, r₃ is the ratio of the non-linear spring constant k₃ over the linear spring constant k₁, and V(t) is drive voltage. Because k₃ is the coefficient for the cubic angular displacement, it is also known as the cubic non-linear spring constant. Furthermore, because the motion of a scanning mirror assembly is constrained by rotation around a fixed axis, a single degree of freedom can be used to approximately describe the motion of the scanning mirror assembly, which may simplify the associated computations.

However, computing the spring constant ratio r₃ using Equation (1) assumes that the scanning mirror assembly is a rigid body, and thus, its shape maintains a single mode or angular displacement at any point in time during oscillation, which may not always be the case. For example, single crystal silicon or polysilicon, both of which are typical materials used to form a scanning mirror assembly by MEMS fabrication processes, each have a Young's modulus around 160 GPa. This means that a scanning mirror assembly formed from these or similar materials have a certain amount of flexibility.

Consequently, the shape of the scanning mirror assembly formed from these materials is composed of many modes (also referred to as “angular displacements”) or multiple sections (also referred to as “nodes”) of the structure having different angular displacements at the same point during operation. However, Equation (1) fails to account for the flexibility and multiple modes of such a scanning mirror assembly when solving for the spring constant ratio r₃. Thus, Equation (1) cannot be used to compute the spring constant ratio r₃ for a non-rigid scanning mirror assembly if a high degree of accuracy is to be achieved.

Thus, there is an unmet need for a method to compute the spring constant ratio for a non-rigid body using a governing equation of motion with a single degree of freedom specified by the angular displacement.

### SUMMARY

Embodiments of the disclosure provide a method for designing a scanning mirror assembly for an optical sensing system. The method may include receiving an initial set of design parameters for the scanning mirror assembly. The method may also include simulating first scanning mirror oscillation based on the initial set of design parameters using a computer model to compute an initial non-linear spring constant associated with at least one spring of the scanning mirror assembly. The method may further include adjusting the set of design parameters for the scanning mirror assembly based on a comparison between the initial non-linear spring constant and a target non-linear spring constant. In certain aspects, the adjusted set of design parameters may include at least one structural alteration to the at least one spring. The method may also include outputting the at least one structural alteration to be implemented on the at least one spring. In certain aspects, the initial set of design parameters and the adjusted set of design parameters may be associated with a same mirror oscillation frequency and linear spring constant.

Embodiments of the disclosure provide an apparatus for designing a scanning mirror assembly for an optical sensing system. The apparatus may include a communication interface configured to receive a set of design parameters of the scanning mirror assembly. The apparatus may further include a memory configured to store a computer model configured to simulate scanning mirror oscillation. The apparatus may further include at least one processor coupled to the memory. The at least one processor may be configured to simulate first scanning mirror oscillation based on the initial set of design parameters using a computer model to compute an initial non-linear spring constant associated with at least one spring of the scanning mirror assembly. The at least one processor may be configured to adjust the set of design parameters for the scanning mirror assembly based on a comparison between the initial non-linear spring constant and a target non-linear spring constant. In certain aspects, the adjusted set of design parameters may include at least one structural alteration to the at least one spring. The at least one processor may be configured to output the at least one structural alteration to be implemented on the at least one spring. In certain aspects, the initial set of design parameters and the adjusted set of design parameters may be associated with a same mirror oscillation frequency and linear spring constant.

Embodiments of the disclosure provide a non-transitory computer-readable medium for designing a scanning mirror assembly. The non-transitory computer-readable medium may be configured to perform a method of simulating scanning mirror oscillation using a set of design parameters. More specifically, the method may include receiving an initial set of design parameters for the scanning mirror assembly. The method may also include simulating first scanning mirror oscillation based on the initial set of design parameters using a computer model to compute an initial non-linear spring constant associated with at least one spring of the scanning mirror assembly. The method may further include adjusting the set of design parameters for the scanning mirror assembly based on a comparison between the initial non-linear spring constant and a target non-linear spring constant. In certain aspects, the adjusted set of design parameters may include at least one structural alteration to the at least one spring. The method may also include outputting the at least one structural alteration to be implemented on the at least one spring. In certain aspects, the initial set of design parameters and the adjusted set of design parameters may be associated with a same mirror oscillation frequency and linear spring constant.

It is to be understood that both the foregoing general description and the following detailed description are exemplary and explanatory only and are not restrictive of the invention, as claimed.

### BRIEF DESCRIPTION OF THE DRAWINGS

FIG. 1 illustrates a block diagram of an exemplary LiDAR system, according to embodiments of the disclosure.

FIG. 2A illustrates a top view of an exemplary scanning mirror design, according to embodiments of the disclosure.

FIG. 2B illustrates a first perspective view of an exemplary scanning mirror assembly, according to embodiments of the disclosure.

FIG. 2C illustrates a second perspective view of an exemplary scanning mirror assembly, according to embodiments of the disclosure.

FIG. 2D illustrates a first expanded view of an exemplary torsion spring of the scanning mirror assembly illustrated in FIG. 2B, according to embodiments of the disclosure.

FIG. 2E illustrates a first graphical representation used to determine the linear and non-linear spring constants of the exemplary torsion spring illustrated in FIG. 2D, according to embodiments of the disclosure.

FIG. 2F illustrates a second expanded view of an exemplary torsion spring of the scanning mirror assembly illustrated in FIG. 2B, according to embodiments of the disclosure.

FIG. 2G illustrates a second graphical representation used to determine the linear and non-linear spring constants of the exemplary torsion spring illustrated in FIG. 2F, according to embodiments of the disclosure.

FIG. 2H illustrates a third expanded view of an exemplary torsion spring of the scanning mirror assembly illustrated in FIG. 2B, according to embodiments of the disclosure.

FIG. 2I illustrates a third graphical representation used to determine the linear and non-linear spring constants of the exemplary torsion spring illustrated in FIG. 2H, according to embodiments of the disclosure.

FIG. 2J illustrates a first partial view of an exemplary scanning mirror assembly with angled torsion springs, according to embodiments of the present disclosure.

FIG. 2K illustrates a second partial view of an exemplary scanning mirror assembly with angled torsion springs, according to embodiments of the present disclosure.

FIG. 2L illustrates a fifth torsion spring configuration, according to embodiments of the present disclosure.

FIG. 2M illustrates an example cantilever with a tension force applied thereto.

FIG. 3 illustrates an exemplary lookup table that correlates inertial force/torque and angular displacement, according to embodiments of the disclosure.

FIG. 4 illustrates a graphical representation of frequency bandwidths associated with different spring constant ratios, according to embodiments of the disclosure.

FIG. 5 illustrates a block diagram of an exemplary system for designing a scanning mirror, according to embodiments of the disclosure.

FIG. 6 illustrates a flow chart of an exemplary method for designing a scanning mirror, according to embodiments of the disclosure.

### DETAILED DESCRIPTION

Reference will now be made in detail to the exemplary embodiments, examples of which are illustrated in the accompanying drawings. Wherever possible, the same reference numbers will be used throughout the drawings to refer to the same or like parts.

To overcome the challenges described above in the BACKGROUND section, the techniques provided by the present disclosure enable simulating scanning mirror assembly oscillation by constructing a computer model that accounts for the assembly's flexibility. More specifically, the disclosed computer model may average the various angular displacements across the surface of the scanning mirror for a given angular acceleration. The angular acceleration may be changed incrementally, and the average angular displacement across the surface of the scanning mirror may be determined for each of these increments of angular acceleration. Then the computer model may determine the torque of the entire scanning mirror assembly as a function of the average angular displacements determined for the scanning mirror, which simplifies the computational complexity without introducing inaccuracies in the generated solutions, as compared to the currently available techniques.

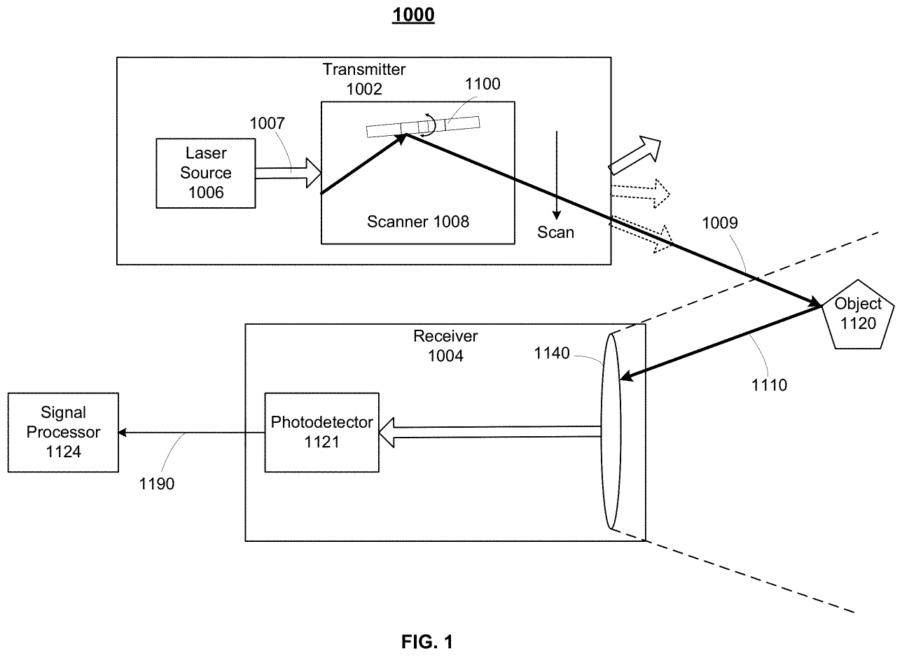

Moreover, the linear spring constant k₁ and non-linear spring constant k₃, and subsequently the spring constant ratio r₃, may be computed based at least in part on polynomial curve fitting of torque as a function of average angular displacement, e.g., additional details of which are described below in connection with FIGS. 1-6. Still further, when the computed spring constant ratio r₃ does not meet a target spring constant ratio r₃′, the set of design parameters may be adjusted (either by user input or adjustments automatically determined by the computer model) and the simulation may be rerun until a set of design parameters is determined that achieves the target spring constant ratio r₃′, e.g., additional details of which are set forth below in connection with FIGS. 1-6.

Some exemplary embodiments are described below with reference to a scanning mirror used in LiDAR system(s), but the application of the scanning mirror assembly disclosed by the present disclosure is not limited to the LiDAR system. Rather, one of ordinary skill would understand that the following description, embodiments, and techniques may apply to any type of optical sensing system (e.g., biomedical imaging, 3D scanning, tracking and targeting, free-space optical communications (FSOC), and telecommunications, just to name a few) known in the art that use a flexible scanning mirror, without departing from the scope of the present disclosure.

FIG. 1 illustrates a block diagram of an exemplary LiDAR system 1000, according to embodiments of the disclosure. LiDAR system 1000 may include a transmitter 1002 and a receiver 1004. Transmitter 1002 may emit laser beams along multiple directions. Transmitter 1002 may include one or more laser sources 1006 and a scanner 1008.

Transmitter 1002 can sequentially emit a stream of pulsed laser beams in different directions within a scan range (e.g., a range in angular degrees), as illustrated in FIG. 1. Laser source 1006 may be configured to provide a laser beam 1007 (also referred to as “native laser beam”) to scanner 1008. In some embodiments of the present disclosure, laser source 1006 may generate a pulsed laser beam in the ultraviolet, visible, or near infrared wavelength range.

In some embodiments of the present disclosure, laser source 1006 may include a pulsed laser diode (PLD), a vertical-cavity surface-emitting laser (VCSEL), a fiber laser, etc. For example, a PLD may be a semiconductor device similar to a light-emitting diode (LED) in which the laser beam is created at the diode's junction. In some embodiments of the present disclosure, a PLD includes a PIN diode in which the active region is in the intrinsic (I) region, and the carriers (electrons and holes) are pumped into the active region from the N and P regions, respectively. Depending on the semiconductor materials, the wavelength of incident laser beam 1007 provided by a PLD may be greater than 700 nm, such as 760 nm, 785 nm, 808 nm, 848 nm, 905 nm, 940 nm, 980 nm, 1064 nm, 1083 nm, 1310 nm, 1370 nm, 1480 nm, 1512 nm, 1550 nm, 1625 nm, 1654 nm, 1877 nm, 1940 nm, 2000 nm, etc. It is understood that any suitable laser source may be used as laser source 1006 for emitting laser beam 1007.

Scanner 1008 may be configured to emit a laser beam 1009 to an object 1120 in a direction within a range of scanning angles. In some embodiments consistent with the present disclosure, scanner 1008 may include a micromachined mirror assembly having a scanning mirror, such as MEMS mirror 1100. In some embodiments, at each time point during the scan, scanner 1008 may emit laser beam 1009 to object 1120 in a direction within a range of scanning angles by rotating the micromachined mirror assembly. MEMS mirror 1100, at its rotated angle, may deflect the laser beam 1007 generated by laser sources 1006 to the desired direction, which becomes laser beam 1009. The micromachined mirror assembly may include various components that enable, among other things, the rotation of the MEMS mirror 1100. For example, the micromachined mirror assembly may include, among other things, a scanning mirror (e.g., MEMS mirror 1100), a first set of anchors, one or more actuators each coupled to an anchor in the first set of anchors, a second set of anchors, at least one torsion spring coupled to at least one anchor in the set of anchors, and a substrate, just to name a few.

Certain design parameters of the MEMS mirror 1100 may impact its performance. Such design parameters may include, e.g., mirror dimensions, Q-factor, comb finger number, distance between comb fingers, length of comb fingers, drive frequency and amplitude, spring dimension, linear spring constant, non-linear spring constant, torsional spring constant, spring constant ratio, torsion spring dimensions, number of torsion springs, torsion spring angle with respect to one or more of the anchor, gimbal, and/or scanning mirror, just to name a few. Thus, it may be beneficial to design a MEMS mirror 1100 by tailoring the design parameters during the design phase such that target performance requirements are met.

The present disclosure provides a method that enables the adjustment of the design parameters during the design phase for a sample scanning mirror assembly, such as one or more MEMS mirror 1100, scanner 1008, and/or transmitter 1002. These adjustments may be made based on the computed spring constant ratio r₃ (also referred to as the “initial spring constant ratio r₃”). For example, an initial spring constant ratio r₃ (also referred to as the “computed spring constant ratio r₃”) computed for an initial set of design parameters may be compared to a target non-linear spring constant ratio r₃′. When the initial non-linear spring constant ratio r₃ meets the target non-linear spring constant ratio r₃′, the initial set of design parameters may be those used to manufacture the scanning mirror assembly. Otherwise, when the initial non-linear spring constant ratio r₃ does not meet the target non-linear spring constant ratio r₃′, an adjusted set of design parameters may be proposed, and the simulation may be rerun based on the adjusted set of design parameters.

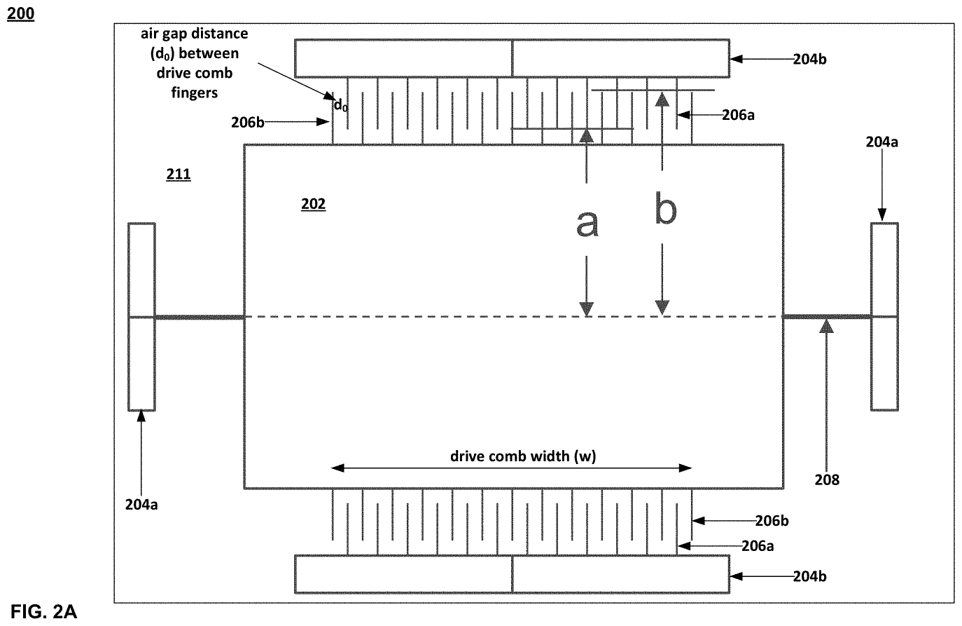

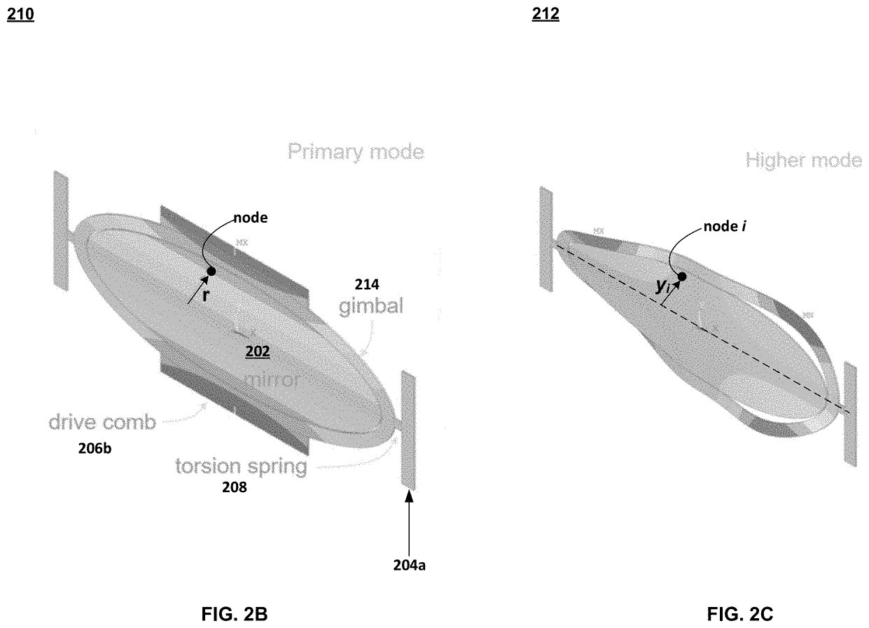

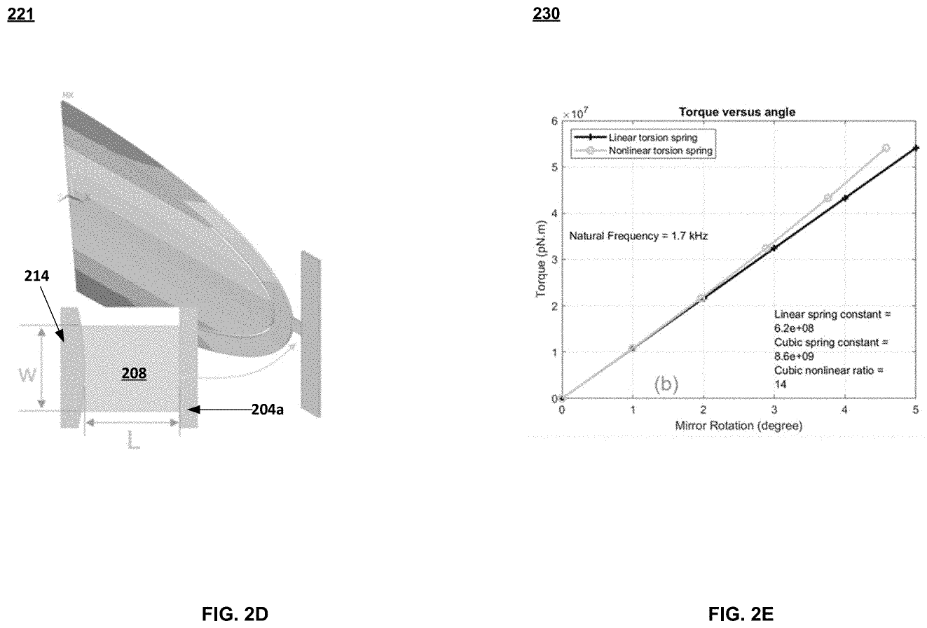

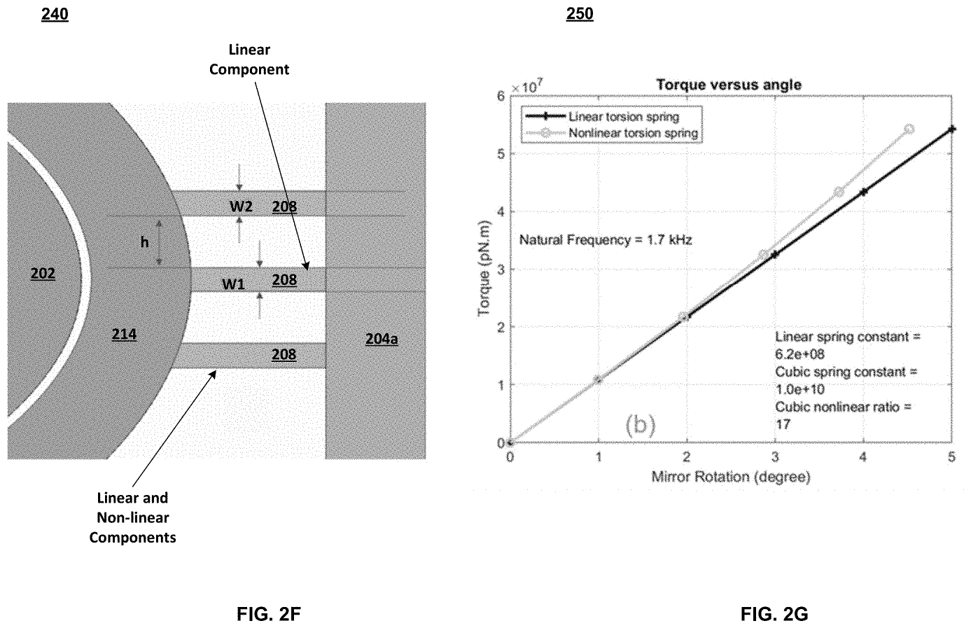

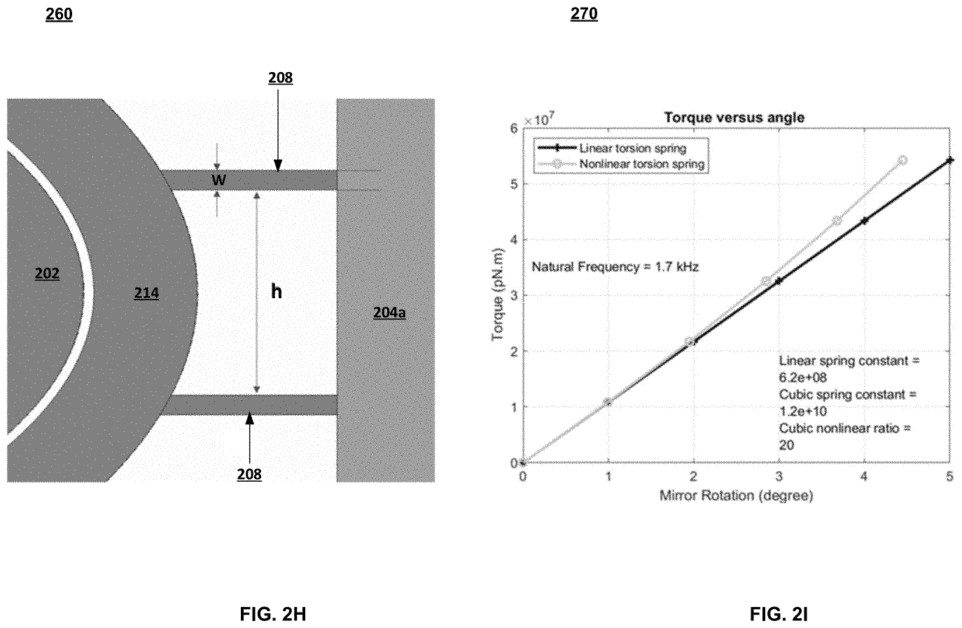

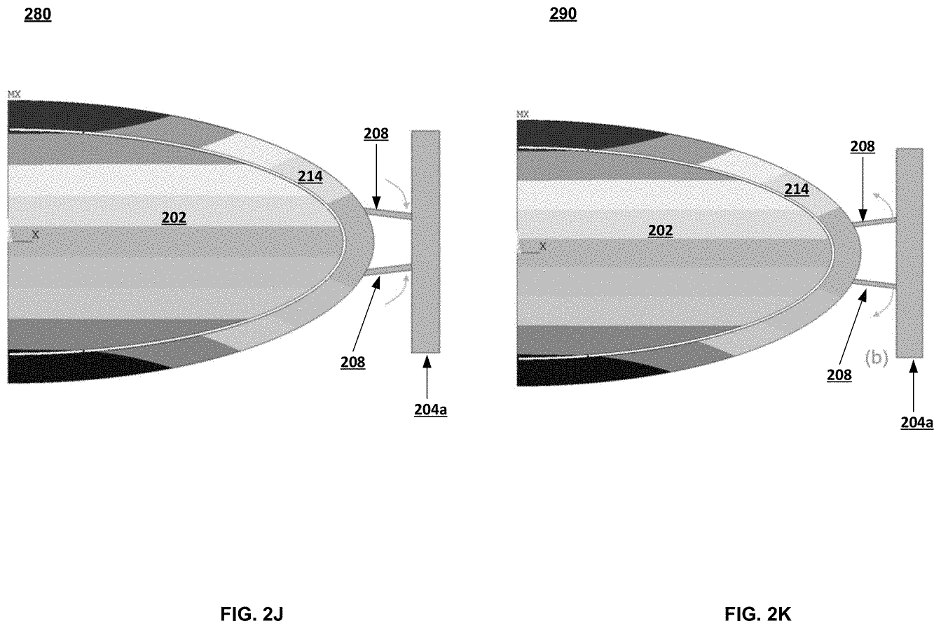

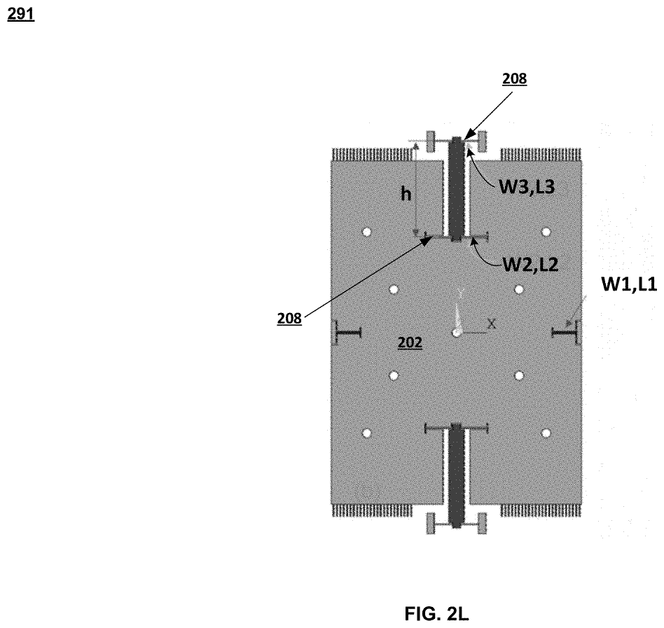

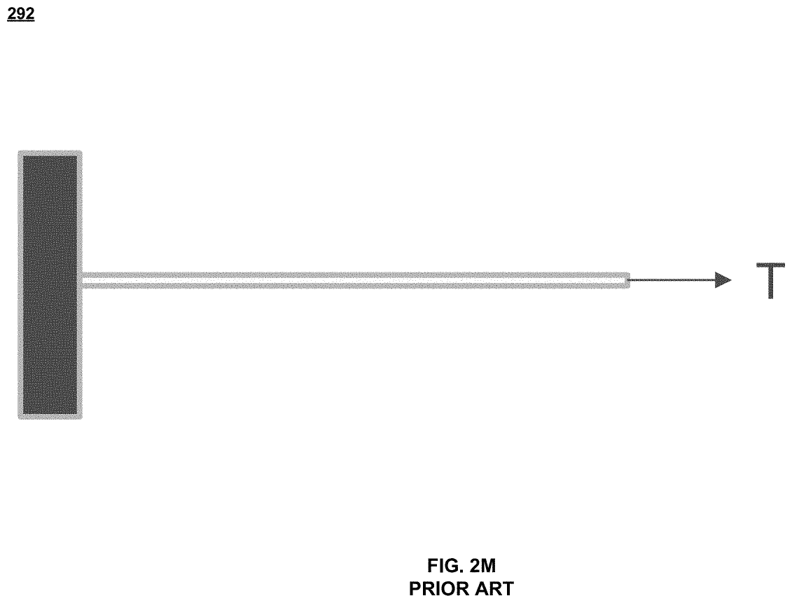

A subsequent determination may be made as to whether the target spring constant ratio r₃′ is met using the adjusted set of design parameters. The set of design parameters may be adjusted until a scanning mirror assembly design that meets the target spring constant ratio r₃′ is achieved. In certain implementations, the method may determine appropriate design alterations based on a comparison of the computed spring constant ratio r₃ and a target spring constant ratio r₃′. The adjusted set of design parameters may be selected such that the characteristics oscillation frequency and the linear spring constant remains constant and only the non-linear spring constant is changed, e.g., additional details of which are set forth below in connection with FIGS. 2-6.

Still referring to FIG. 1, object 1120 may be made of a wide range of materials including, for example, non-metallic objects, rocks, rain, chemical compounds, aerosols, clouds and even single molecules. In some embodiments of the present disclosure, scanner 1008 may also include optical components (e.g., lenses) that can focus pulsed laser light into a narrow laser beam to increase the scan resolution.

In some embodiments, receiver 1004 may be configured to detect a laser beam 1110 returned from object 1120. The returned laser beam 1110 may be in a different direction from laser beam 1009. Receiver 1004 can collect laser beams returned from object 1120 and output electrical signals reflecting the intensity of the returned laser beams. Upon contact, laser light can be reflected by object 1120 via backscattering, such as Raman scattering and/or fluorescence. As illustrated in FIG. 1, receiver 1004 may include a lens 1140 and a photodetector 1121. Lens 1140 may be configured to collect light from a respective direction in its FOV and converge the laser beam to focus before it is received on photodetector 1121. At each time point during the scan, returned laser beam 1110 may be collected by lens 1140. Returned laser beam 1110 may be returned from object 1120 and have the same wavelength as laser beam 1009.

Photodetector 1121 may be configured to detect returned laser beam 1110 returned from object 1120. In some embodiments, photodetector 1121 may convert the laser light (e.g., returned laser beam 1110 ) collected by lens 1140 into an electrical signal 1190 (e.g., a current or a voltage signal). Electrical signal 1190 may be generated when photons are absorbed in a photodiode included in photodetector 1121. In some embodiments of the present disclosure, photodetector 1121 may include a PIN detector, a PIN detector array, an avalanche photodiode (APD) detector, a APD detector array, a single photon avalanche diode (SPAD) detector, a SPAD detector array, a silicon photo multiplier (SiPM/MPCC) detector, a SiP/MPCC detector array, or the like.

LiDAR system 1000 may also include one or more signal processor 1124. Signal processor 1124 may receive electrical signal 1190 generated by photodetector 1121. Signal processor 1124 may process electrical signal 1190 to determine, for example, distance information carried by electrical signal 1190. Signal processor 1124 may construct a point cloud based on the processed information. Signal processor 1124 may include a microprocessor, a microcontroller, a central processing unit (CPU), a graphical processing unit (GPU), a digital signal processor (DSP), or other suitable data processing devices.

FIG. 2A illustrates a top view of an exemplary scanning mirror design 200, according to embodiments of the disclosure. Various aspects of the scanning mirror design 200 may be used (e.g., during the design phase) to compute performance characteristics of a scanning mirror 202 (e.g., MEMS mirror 1100).

For example, the scanning mirror design 200 may include an initial set of design parameters that may be used to compute the associated non-linear spring constant. In some embodiments, the initial set of design parameters may be associated with one or more components of a scanning mirror assembly. Such components may include at least one of, e.g., a scanning mirror 202 (e.g., MEMS mirror 1100), a first set of anchors 204a, a second set of anchors 204b, fixed drive comb fingers 206a coupled to anchors 204b, sliding comb drive fingers 206b coupled to the scanning mirror 202, one or more torsion springs 208, and/or a substrate 211, just to name a few.

In some embodiments, the initial set of design parameters may be parameters of these components, and any change to these parameters may affect the linear spring constant k₁, the non-linear spring constant ratio k₃, and the spring constant ratio r₃, and hence, the oscillation frequency bandwidth of the assembly. For example, the initial set of design parameters may include dimensions (e.g., length, width, and thickness) of the above components, e.g., dimensions of the scanning mirror 202 and dimensions of the drive comb, and distances between these components, e.g., the distance between the scanning mirror 202 and the anchors 204b. Other examples of the initial set of design parameters may include one or more of the materials of these components, the characteristic frequency of the scanning mirror 202, the total overlap area for all drive comb fingers 206a, 206b, air gap spacing between components (e.g., the air gap between fixed drive comb fingers 206a and the sliding comb drive fingers 206b), drive voltage frequency, silicon density, and the moment of inertia of the scanning mirror, just to name a few.

In some embodiments, the linear spring constant k₁, non-linear spring constant k₃, and spring constant ratio r₃ may be computed using the initial set of design parameters and computations according to, e.g., Equations (2) and (5)-(7) set forth below.

To implement a numerical simulation that computes the linear spring constant k₁, non-linear spring constant k₃, and spring constant ratio r₃ for a flexible scanning mirror assembly, the computer model of the present disclosure may convert the above dimensional Equation (1) into non-dimensional Equation (2), by introducing a non-dimensional time τ. Computing solutions for non-dimensional Equation (2) may simplify the computations performed during the scanning mirror simulation. In terms of oscillation frequency, dimensions of Hz (1 Hz=1 revolution per second) or kHz are typically used. However, when performing mathematical computations, dimensions of Hz is not numerically compatible, and hence, non-dimensional ‘radians’ may be used by the disclosed computer model. The computer model of the present disclosure may be configured to divide the time step (e.g., two time steps, ten time steps, 20 time steps, 100 time steps, etc.) to numerically integrate Equation (2):

$$\frac{{\partial }^{2} θ}{\partial {τ}^{2}} + \frac{1}{Q} \frac{\partial θ}{\partial τ} + ( θ + {r}_{3} {θ}^{3} ) = {\sum }_{i = 1}^{N} \frac{f ( θ ) {L}_{i}}{k} {V}^{2} ( τ ) \qquad ( 2 )$$

where τ is a non-dimensional time such that the natural frequency of Equation (2) becomes 2π. When the scanning mirror assembly is driven at or near its natural frequency, the magnitude of the angular displacement, θ, is controlled primarily by the quality factor Q of the scanning mirror, and is linearly proportional to drive torque, and inversely proportional to torsional spring constant k, which may also be referred to as “linear spring constant”). For mirror oscillation, the linear spring constant is the torsion spring constant because the motion is rotary. In other words, ‘k’ in Equation (2) is the same ‘k’ as in Equation (1).

As a scanning mirror assembly rotates, a tension force T is generated along the spring as the scanning mirror assembly rotates, which is responsible for the non-linear spring constant k₃, as described below in connection to the example cantilever assembly 292 of FIG. 2M. Referring to FIG. 2M, the characteristic oscillation frequency fₙ of the example cantilever assembly 292 without a tension force ‘T’ can be described according to Equation (3) shown below:

$${f}_{n} = β \sqrt{\frac{EI}{w {L}^{4}}} \qquad ( 3 )$$

where β is geometry dependent constant, EI is the flexural rigidity of the cantilever beam, w is the width of the cantilever beam, and L is the length of the cantilever beam.

When a tension force T is present along the cantilever beam, its natural frequency fₜₒₜₐₗ becomes larger as shown below in Equation (4):

$${f}_{total} = α \sqrt{\frac{T}{4 {L}^{2}}} + β \sqrt{\frac{EI}{w {L}^{4}}} \qquad ( 4 )$$

where α is another geometry dependent constant, the

$$‘ α \sqrt{\frac{T}{4 {L}^{2}}} ’$$

term is the first frequency component from tension force T and the

$$‘ β \sqrt{\frac{EI}{w {L}^{4}}} ’$$

term is from the bending or twisting of the cantilever beam.

A larger natural frequency fₜₒₜₐₗ corresponds to a stiffer spring. In other words, a stiffer spring requires a larger force (torque) to rotate about an axis, which is the effect of the non-linear spring constant k₃. In other words, the larger the angular displacement, the larger the torque required to turn.

The non-linear spring constant k₃ is cubic (3^{rd} order) due to the symmetric nature of scanning mirror assembly design. If the non-linear spring is quadratic (2^{nd} order), the scanning mirror assembly would be asymmetric. In other words, an asymmetric scanning mirror assembly would experience different torques when rotating in a positive direction as opposed to a negative direction.

Considering that a spring is made up of an infinite number of fibers, the fiber along the axis of rotation contributes only to the linear spring constant k₁. All other fibers contribute both to both the linear spring constant k₁ and nonlinear spring constant k₃. The fibers at the outer most of the spring contribute most to the non-linearity.

Both the linear spring constant k₁ and the nonlinear spring constant k₃ are functions of the spring dimensions and shapes. Therefore, the computer model and/or user can manipulate both dimensions and shapes of the springs to search for a target pair of linear spring constant k₁ and non-linear spring constant k₃.

Assuming the torsion spring is cubic non-linear, then the relationship between torque and angular displacement B can be expressed as a polynomial as shown below in Equation (5):

torques=k₁θ¹+k₃θ³=kθ(1+r₃θ²) (5)

where r₃ is the spring constant ratio of the non-linear spring constant k₃ over the linear spring constant k₁, and k=k₁.

As previously mentioned, to solve for the linear spring constant k₁, non-linear spring constant k₃, and spring constant ratio r₃ for a flexible scanning mirror assembly, the associated governing equation of motion must account for the assembly's flexibility if a high degree of accuracy is to be achieved. To compute the linear spring constant k₁, non-linear spring constant k₃, and spring constant ratio r₃ for a flexible scanning mirror assembly, the disclosed method simulates scanning mirror assembly oscillation by constructing a computer model that accounts for the assembly's flexibility, e.g., as will be described in additional detail below in connection with FIGS. 2B-6.

FIG. 2B depicts an exemplary scanning mirror assembly 210 in primary oscillation mode. FIG. 2C depicts an exemplary scanning mirror assembly 212 in higher oscillation mode, according to embodiments of the present disclosure. FIGS. 2B and 2C may depict the same scanning mirror assembly oscillating in different oscillation modes, e.g., primary and higher, respectively. FIG. 2D illustrates an expanded view 221 of a first torsion spring configuration for the exemplary scanning mirror assembly 212 of FIG. 2C, according to embodiments of the present disclosure. FIG. 2E is a first graphical representation 230 of linear torque versus angular displacement and non-linear torque versus angular displacement associated with the first torsion spring configuration of FIG. 2D, according to embodiments of the present disclosure. FIG. 2F illustrates an expanded view 240 of a second torsion spring configuration for the exemplary scanning mirror assembly 212 of FIG. 2C, according to embodiments of the present disclosure. FIG. 2G is a second graphical representation 250 of linear torque versus angular displacement and non-linear torque versus angular displacement associated with the second torsion spring configuration of FIG. 2F, according to embodiments of the present disclosure. FIG. 2H illustrates an expanded view 260 of a third torsion spring configuration for the exemplary scanning mirror assembly 212 of FIG. 2C, according to embodiments of the present disclosure. FIG. 2I is a third graphical representation 270 of linear torque versus angular displacement and non-linear torque versus angular displacement associated with the third torsion spring configuration of FIG. 2H, according to embodiments of the present disclosure. FIG. 2J illustrates an expanded view 280 of a fourth torsion spring configuration for the exemplary scanning mirror assembly 212 of FIG. 2C, according to embodiments of the present disclosure. FIG. 2K illustrates an expanded view 290 of a fifth torsion spring configuration for the exemplary scanning mirror assembly 212 of FIG. 2C, according to embodiments of the present disclosure. FIG. 2L illustrates a fifth torsion spring configuration, according to embodiments of the present disclosure. FIGS. 2B-2L will be described together.

FIG. 2B depicts an exemplary scanning mirror assembly 210 that includes an elliptical scanning mirror 202 and gimbal 214, a set of comb drive fingers 206b coupled to the gimbal 214, and a torsion spring 208 that couples gimbal 214 to anchor 204a. During oscillation, each point (also referred to as “node”) on the surface of the rigid scanning mirror assembly 210 has the same angular displacement associated with a given angular acceleration, which is also referred to as “primary oscillation mode.”

On the other hand, FIG. 2C depicts an exemplary scanning mirror assembly 220 with similar components, dimensions, and shape as the exemplary scanning mirror assembly 210 depicted in FIG. 2B except that the scanning mirror assembly is oscillating in higher oscillation mode. For simplicity, the comb drive fingers 206b are not shown here. During oscillation, as depicted in FIG. 2C, different points, sections, regions, or nodes on the surface of scanning mirror assembly 220 may have different angular displacements associated with a given angular acceleration, which is also referred to as “higher oscillation mode.” When oscillating in higher mode, the surface of the scanning mirror assembly 220 may not remain flat due to the lack of rigidity. Physically, the scanning mirror shape may a combination of the primary mode and one or more higher modes (e.g., there may be a plurality of higher oscillation modes). Therefore, a scanning mirror may never be truly flat during oscillation. Thus, the present disclosure may compute the linear spring constant k₁ and non-linear sprint constant k₃ by averaging these values across the entire surface of scanning mirror 202.

In some embodiments, the linear spring constant k₁, non-linear spring constant k₃, and spring constant ratio r₃ for flexible scanning mirror assembly 220 may be computed using the initial set of design parameters and computations according to, e.g., Equations (6) and (7) set forth below. The computer model (e.g., ANSYS ADPL, Simulink schematic ordinary differential equation (ODE) solver, etc.) may use the solutions for Equations (6) and (7) to solve for a numerical simulation of non-dimensional Equation (2) shown above. Once the solutions to non-dimensional Equation (2) have been found, they may be converted back into quantities with dimensions to solve for Equation (1).

More specifically, the computer model may generate a simulation of a flexible scanning mirror assembly based on a set of initial design parameters. The initial set of design parameters may be input into the computer model by a user or the computer model may select the initial set of design parameters from sample design parameters. Then, the computer model may simulate the mirror oscillation when an angular acceleration \ddot{θ} is applied to the simulated flexible scanning mirror assembly 220. The angular acceleration \ddot{θ} used for the simulation may be selected such that the simulated scanning mirror 202 oscillates at a frequency associated with a predetermined scanning angle (e.g., such as 5 mechanical degrees) that falls within a range of scanning angles up to the maximum scanning angle associated with a particular scanning mirror assembly design. As will be described, the computer model may repeat the simulation for different angular accelerations. Under each angular acceleration \ddot{θ}, the simulated scanning mirror 202, gimbal 214, and torsion spring 208 may deform in their natural shape, such as the example depicted in FIG. 2C, that is the same or similar as the natural shape associated with oscillatory motion during a scanning procedure.

To simplify computations associated with determining torque as a function of angular displacement θ, the computer model may first compute the average angular displacement θ for all nodes across the entire surface of the scanning mirror 202. For example, the computer model may determine the average angular displacement of all nodes using Equation (6) for a given angular acceleration \ddot{θ}:

$$θ = \frac{1}{n} {\sum }_{i = 1}^{n} {tan}^{- 1} \frac{{z}_{i}}{{y}_{i}} \approx \frac{1}{n} {\sum }_{i = 1}^{n} \frac{{z}_{i}}{{y}_{i}} \qquad ( 6 )$$

where n is the total number of nodes over the surface of the scanning mirror 202 in the numerical model (also referred to as a “simulation”), zᵢ is vertical displacement of node i, yᵢ is distance from node i relative to the axis of rotation.

Then under the same angular acceleration \ddot{θ}, the resulting torque can be computed for all rotating bodies in the assembly (e.g., scanning mirror 202, gimbal 214, comb drive fingers 206b) using Equation (7) seen below:

torque(θ)= [symbol] \ddot{θ}r²dm (70

where r is distance from a mass element “dm” to the axis of rotation. The three-dimensional integration covers the entire rotating bodies (e.g., scanning mirror 202, gimbal 214, comb drive fingers 206b) in the assembly.

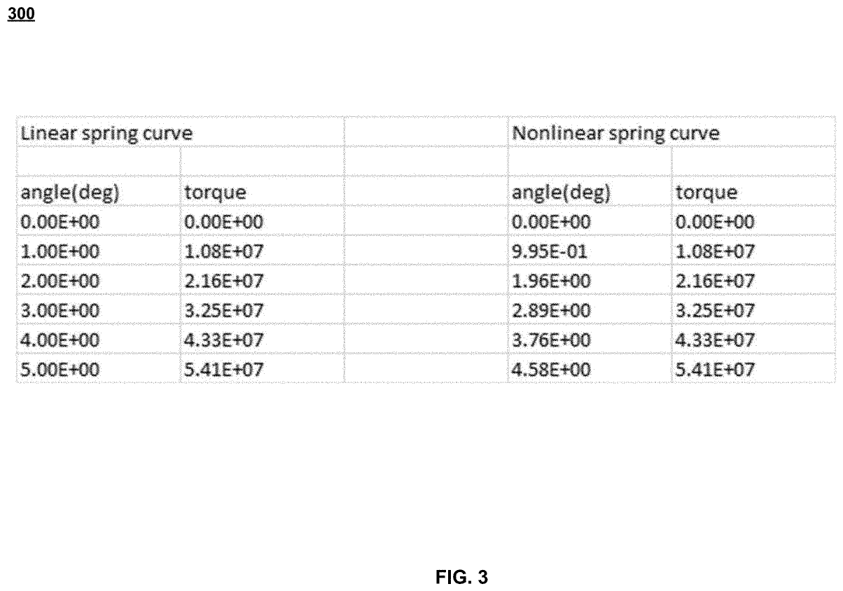

Then, the angular acceleration \ddot{θ} may be changed incrementally, and the average angular displacement θ may be computed for each of these increments of angular acceleration. The angular accelerations \ddot{θ} may be those associated with different scanning angles. Then the computer model may compute the torque of the entire scanning mirror assembly as a function of the average angular displacement associated with that angular acceleration, and so on until torque as a function of angular displacement for each of the simulated angular accelerations have been computed. The computer model may save the resulting data as a lookup table that correlates torque and angular displacement, an example of which is shown in FIG. 3. The lookup table may include torque and angular displacement values that are used to plot polynomial curves to compute the linear spring constant k₁ and non-linear spring constant k₃, e.g., as described below in connection with FIGS. 2D, 2F, and 2H. In certain implementations, the angular displacement may be converted from degree to radian prior to performing the polynomial curve fitting.

Finally, for a scanning mirror assembly design using the initial set of design parameters, for a given relation between angular displacement and torque for a particular design, the computer model may compute the linear spring constant k₁ and the cubic non-linear spring constant k₃ using cubic polynomial curve fitting, examples of which are depicted in FIGS. 2E, 2G, and 2I. The spring constant ratio r₃ may be computed as r₃=k₃/k₁.

The computer model may compare r₃ computed for the initial set of design parameters with a target spring constant ratio r₃′ to determine whether these design parameters achieve the desired result. If the initial set of design parameters achieves the target linear spring constant k₁′, the target non-linear spring constant k_{3′}, the target spring constant ratio r_{3′}, the computer model may output such an indication. Otherwise, if the initial set of design parameters does not achieve one or more of the target non-linear spring constant k_{3′}, the target spring constant ratio r₃′, an adjusted set of design parameters may be proposed either by the computer model or as an input from a user and the simulation rerun.

The adjusted set of design parameters may include, e.g., at least one structural alteration to the at least one spring. More specifically, the at least one structural alteration may include a change in size of the at least one spring, a change in number of springs of the at least one spring, a change in spacing between two or more springs of the at least one spring, a change in angle between the at least one spring and a component of the scanning mirror assembly, a change in scanning mirror assembly type, as depicted in FIGS. 2D, 2F, 2H, and 2L.

In implementations in which a target linear spring constant k₁′, and hence, the target characteristic oscillation frequency is achieved using the initial set of design parameters, the structural alterations may be selected such that the non-linear spring constant k₃ is adjusted (to increase spring constant ratio r₃) without changing the linear spring constant k₁, thereby increasing the oscillation frequency bandwidth without changing the characteristic oscillation frequency of the scanning mirror assembly.

For example, the initial set of design parameters may include a torsion spring 208 with the dimensions seen in FIG. 2D. FIG. 2D illustrates half of a symmetric structure of an elliptical scanning mirror design where the torsion spring 208 looks like a “rectangle.” The spring stiffness and the requirement of characteristic frequency of a particular scanning mirror assembly application dictate the choice of spring length L and spring width w.

FIG. 2E illustrates torque as a function of angular displacement curves (shown in first graphical representation 230) associated with the initial set of design parameters. One is a linear plot that may be computed by ignoring the non-linearity in the computation. The second is a non-linear curve computed including geometric non-linearity as the scanning mirror assembly is rotated. As the mirror angle becomes larger, additional torque is required, a phenomenon that may also be referred to as “spring stiffening.” Physically, the non-linearity is caused by stretching of material toward up edge or down edge of the spring along the length direction. Therefore, a wider torsion spring would imply a more non-linear spring. For a linear spring, the set of design parameters may include a comparatively small w and large L.

Assuming 1.7 kHz is the target characteristic oscillation frequency, it can be achieved by experimenting and properly choosing values of L & w. As shown in the example depicted in FIG. 2E, for a L of 500 μm and w of 300 μm, a linear spring constant k₁ of 6.2×10⁸ would yield the required frequency of 1.7 kHz, and at the same time, the non-linear spring constant k₃ is 8.6×10⁹. In this example, the spring constant ratio r₃ is 14 as shown in FIG. 2E. Other dimensions than the values given for L and w in connection with FIG. 2D may be used without departing from the scope of the present disclosure.

By way of example, assuming that the target spring constant ratio r₃′ is 20, the initial set of design parameters of FIG. 2D therefore does not achieve the target spring constant ratio r₃′. Accordingly, either the computer model may suggest an adjusted set of design parameters or they may be input by a user.

For illustrative purposes, the adjusted set of design parameters may result in mirror designs as those depicted in FIG. 2F. For example, FIG. 2F illustrates half of a symmetric structure of an elliptical scanning mirror design where the torsion spring 208 includes a “triple spring design.” The triple torsion spring 208 of FIG. 2F includes four design parameters that may be tailored to adjust the non-linear spring constant k₃. These four design parameters include, e.g., length L of 700 μm, width w1 of 120 μm, width w2 of 120 μm, and gap h of 260 μm. Assuming the target characteristic oscillation frequency is 1.7 kHz, these four spring parameters may be tailored such that the linear spring constant k₁ remains 6.2×10⁸ and the non-linear spring constant k₃ is increased. As shown in FIG. 2G, the adjusted set of design parameters illustrated in FIG. 2F increased the non-linear spring constant k₃ from 8.6×10⁹ to 1.0×10¹⁰. The spring constant ratio r₃ is increased to 17 as compared to the spring constant ratio associated with the initial set of design parameters illustrated in FIG. 2D. By increasing the number of design parameters from two in FIG. 2D to four in FIG. 2F, there number of possible design parameter combinations that may be tailored by a design engineer to achieve the target linear and non-linear spring constants may also be increased from two to four. Increasing the number of possible design parameter combinations that can possibly achieve the target linear and non-linear spring constants may simplify a design engineer's search for design parameters that achieve these target spring constant values. Other dimensions than the values given for L , w1, w2, and gap h in connection with FIG. 2F may be used without departing from the scope of the present disclosure.

With the assumption that the target spring constant ratio r₃′is 20, the adjusted set of design parameters of FIG. 2F yields a spring constant ratio r₃ that is closer but still falls short to achieve the target spring constant ratio r₃′. Thus, either the computer model may suggest a subsequent adjusted set of design parameters or they may be input by a user.

For illustrative purposes, the subsequent adjusted set of design parameters may result in mirror designs as those depicted in FIG. 2H. For example, FIG. 2H illustrates half of a symmetric structure of an elliptical scanning mirror design where the torsion spring 208 includes a “double spring design,” where the middle torsion spring shown in FIG. 2F is removed. For such a spring design, there are three parameters (e.g., length L of 800 μm, width w of 95 μm, and gap h of 1000 μm) that may be changed to increase the non-linear spring constant k₃ without changing the linear spring constant k₁. As illustrated in FIG. 2I, the subsequent adjusted set of design parameters increase the non-linear spring constant k₃ is increased from 8.6×10⁹ to 1.2×10¹⁰ as compared to the spring design illustrated in FIG. 2F. Here, the target spring constant ratio r₃′ is 20 is achieved. Other dimensions than the values given for L , w, and h in connection with FIG. 2F may be used without departing from the scope of the present disclosure.

In some embodiments, both the linear spring constant k₁ and non-linear spring constant k₃ to achieve the target spring constant ratio r₃′. For example, the adjusted set of design parameters illustrated in FIGS. 2J and 2K including tilting the springs ‘inward’ or ‘outward,’ respectively, to change both the linear spring constant k₁ and non-linear spring constant k₃. The amount the springs 208 are tilted depends on the target requirements for a particular application.

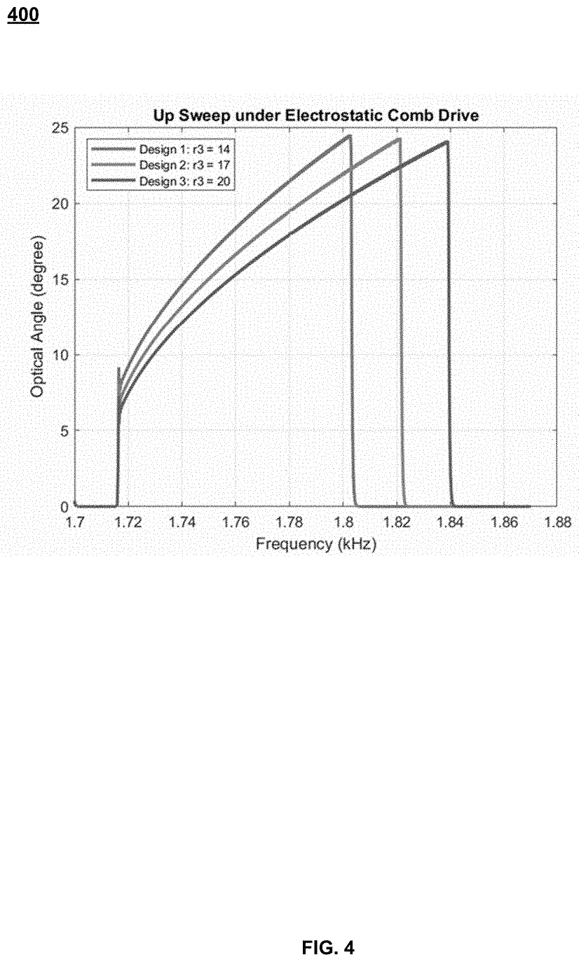

For each of ratio r₃, by applying all other design parameters to the computer model and by applying a sinusoidal drive voltage, a frequency response curve (e.g., such as the one illustrated in FIG. 4) can be simulated that covers a frequency range starting from slightly below the natural frequency to well above the natural frequency. The frequency range was made large enough to reveal or show a sudden drop in mirror angle. Under the same design parameter values and repeating the simulation for r₃=14, 17, & 20, there are three frequency response curves as shown in FIG. 4. The impact of spring constant ratio r₃ is that the oscillation frequency bandwidth for a scanning mirror assembly design increases with spring constant ratio r₃. As mentioned above, designing a scanning mirror assembly such that the set of design parameters maximize the associated oscillation frequency bandwidth while maintaining a desired characteristic oscillation frequency may be advantageous in terms of controlling the scanning mirror angle during use by adjusting the drive frequency in the accompanying scanner electronics.

When an even higher non-linear spring constant is desired, a teeter totter type torsion spring may be used as the adjusted set of design parameters as illustrated in FIG. 2L. A higher non-linear spring constant k₃ requires a larger tension force in the torsion spring as the scanning mirror assembly rotates. A larger tension force implies a longer longitudinal stretch in the spring 208.

As seen in FIG. 2L, spring 1 (W1, L1) is a torsion spring lying along the rotation axis and in addition to twisting, it stays in the mirror plane. Spring 2 (W2, L2) is attached to scanning mirror 202 far away from the rotation axis and it would travel large distance along ‘Z’ as mirror rotates.

In the design illustrated in FIG. 2L, spring 3 (W3, L3) may be anchored onto a substrate (not shown). Spring 2 and spring 3 may be connected via a linkage bar of length h, which is practically a rigid bar along its length direction. As the scanning mirror assembly rotates, the distance between spring 2 and spring 3 increases. Since the linkage bar is ‘rigid,’ it results pulling between the two springs and thus a large tension force inside the springs along the spring length direction occurs. The non-linearity depends on the spring dimensions (W2, L2, W3, L3) as well as the separation h, and hence, may be selected according to target linear spring constant k₁′, target non-linear spring constant k₃′, and the target characteristic oscillation frequency.

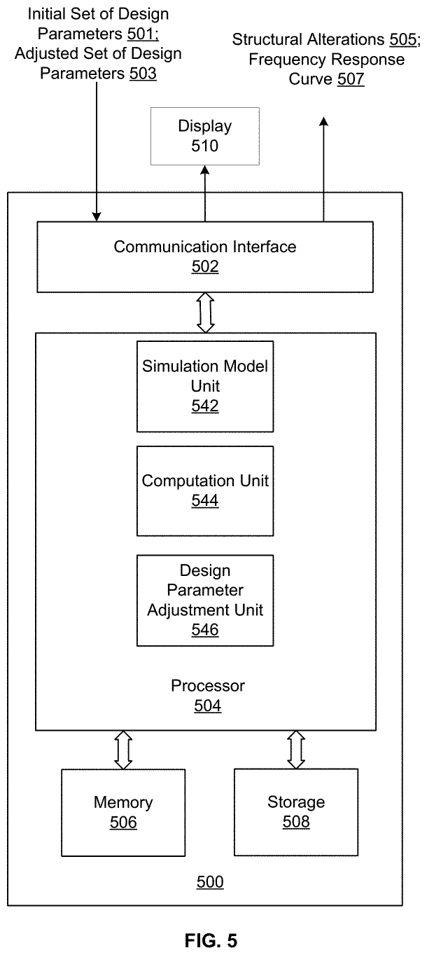

FIG. 5 illustrates a block diagram of an exemplary system 500 for designing a scanning mirror (e.g., MEMS mirror 1100 of FIG. 1), according to embodiments of the disclosure. In some embodiments, as shown in FIG. 5, system 500 may include a communication interface 502, a processor 504, a memory 506, and a storage 508. In some embodiments, system 500 may have different modules in a single device, such as an integrated circuit (IC) chip (e.g., implemented as an application-specific integrated circuit (ASIC) or a field-programmable gate array (FPGA)), or separate devices with dedicated functions. In some embodiments, one or more components of system 500 may be located in a cloud or may be alternatively in a single location (such as inside a mobile device) or distributed locations. Components of system 500 may be in an integrated device or distributed at different locations but communicate with each other through a network (not shown). Consistent with the present disclosure, system 500 may be configured to determine the design parameter values of the scanning mirror.

Communication interface 502 may send data to and receive data from databases via communication cables, a Wireless Local Area Network (WLAN), a Wide Area Network (WAN), wireless networks such as radio waves, a cellular network, and/or a local or short-range wireless network (e.g., Bluetooth™), or other communication methods. In some embodiments, communication interface 502 may include an integrated service digital network (ISDN) card, cable modem, satellite modem, or a modem to provide a data communication connection. As another example, communication interface 502 may include a local area network (LAN) card to provide a data communication connection to a compatible LAN. Wireless links can also be implemented by communication interface 502. In such an implementation, communication interface 502 can send and receive electrical, electromagnetic or optical signals that carry digital data streams representing various types of information.

Consistent with some embodiments, communication interface 502 may receive an initial set of design parameters 501 and/or an adjusted set of design parameters 503 from a database or a user input (not shown). Communication interface 502 may further provide the initial set of design parameters 501 to memory 506 and/or storage 508 for storage or to processor 504 for processing.

Processor 504 may include any appropriate type of general-purpose or special-purpose microprocessor, digital signal processor, or microcontroller. Processor 504 may be configured as a separate processor module dedicated to simulating scanning mirror oscillation and computing performance characteristics based on the initial set of design parameters 501. Processor 504 may be configured to execute a computational toolbox to perform a series of computations. The computational toolbox may include a plurality of functional blocks configured as a computer model for simulating the scanning mirror oscillation. Alternatively, processor 504 may be configured as a shared processor module for performing other functions in addition to determining design parameter values and making design changes of the scanning mirror.

Memory 506 and storage 508 may include any appropriate type of mass storage provided to store any type of information that processor 504 may need to operate. Memory 506 and storage 508 may be a volatile or non-volatile, magnetic, semiconductor, tape, optical, removable, non-removable, or other type of storage device or tangible (i.e., non-transitory) computer-readable medium including, but not limited to, a ROM, a flash memory, a dynamic RAM, and a static RAM. Memory 506 and/or storage 508 may be configured to store one or more computer programs that may be executed by processor 504 to perform functions disclosed herein. For example, memory 506 and/or storage 508 may be configured to store program(s) that may be executed by processor 504 to determine design parameter values of the scanning mirror.

In some embodiments, memory 506 and/or storage 508 may also store various scanning mirror design parameters including e.g., initial design parameters and adjusted design parameters associated with structural alterations (e.g., one or more of a change in size of the at least one spring, a change in number of springs of the at least one spring, a change in spacing between two or more springs of the at least one spring, a change in angle between the at least one spring and a component of the scanning mirror assembly, just to name a few), target performance characteristics for various scanning mirror designs, one or more look-up tables that correlate electrostatic force as a function of angular displacement for various scanning mirror designs, and/or a computer model configured to simulate scanning mirror oscillation, etc. Memory 506 and/or storage 508 may also store information associated with Equations (1)-(7) used to simulate scanning mirror oscillation and to compute performance characteristics, linear spring constant k₁, the non-linear spring constant k₃, and the spring constant ratio r₃ as a result of the simulation, etc.

As shown in FIG. 5, processor 504 may include multiple modules, such as a simulation model unit 542, computation unit 544, a design parameters adjustment unit 546, and the like. These modules (and any corresponding sub-modules or sub-units) can be hardware units (e.g., portions of an integrated circuit) of processor 504 designed for use with other components or software units implemented by processor 504 through executing at least part of a program. The program may be stored on a computer-readable medium, and when executed by processor 504, it may perform one or more functions. Although FIG. 5 shows units 542-546 all within one processor 504, it is contemplated that these units may be distributed among different processors located closely or remotely with each other. For example, units 542-544 may be part of a separate simulation device and unit 546 may be part of a design parameter generation device. In certain implementations, one or more of units 542-546 may be omitted, depending on the specific design task.

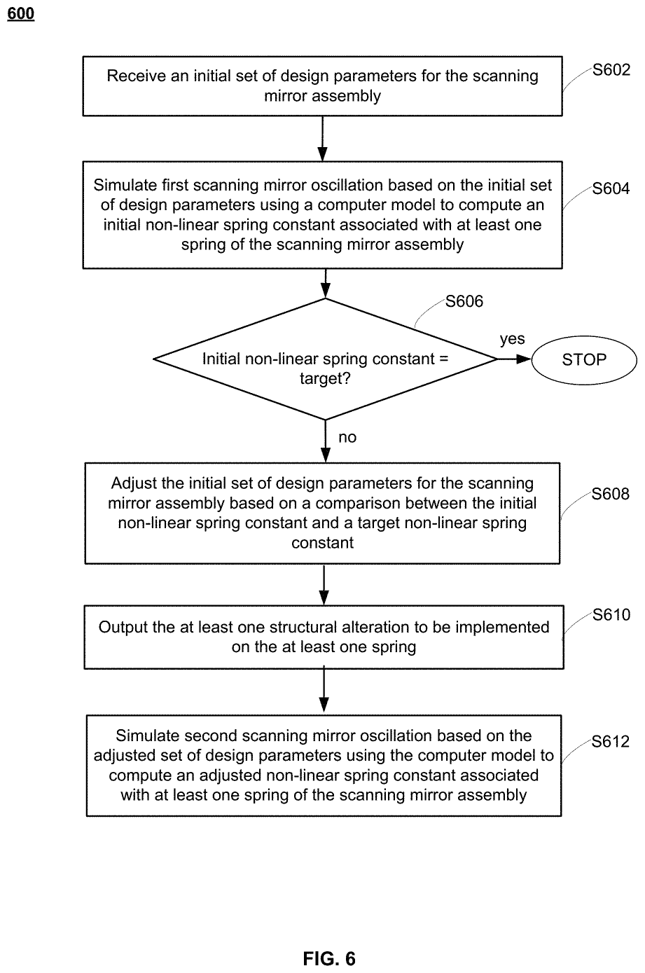

In some embodiments, one or more of units 542-546 of FIG. 5 may execute computer instructions to design a scanning mirror. FIG. 6 illustrates a flowchart of an exemplary method 600 for designing scanning mirrors, according to embodiments of the disclosure. Method 600 may be performed by system 500 and particularly processor 504 or a separate processor not shown in FIG. 5. Method 600 may include steps S602-S612 as described below. It is to be appreciated that some of the steps may be optional, and some of the steps or sub-steps may be performed simultaneously, or in a different order than shown in FIG. 6. FIGS. 5 and 6 will be described together, as shown below.

In step 602, communication interface 502 may receive an initial set of design parameters 501 (e.g., design parameters associated with scanning mirror design 200 of FIG. 2) of the scanning mirror. The initial set of design parameters 501 may include, e.g., mirror size, Q-factor, comb finger number, distance between comb fingers, length of comb fingers, drive frequency and amplitude, and spring dimensions, just to name a few.

In step 604, the simulation model unit 542 may simulate first scanning mirror oscillation based on the initial set of design parameters 501 using a computer model to compute an initial non-linear spring constant associated with at least one spring of the scanning mirror assembly. Step 604 may include one or more sub-steps as described below.

For example, referring to one aspect of step 604, simulation model unit 542 may simulate scanning mirror oscillation by determining a plurality of nodes associated with a scanning mirror of the scanning mirror assembly, the scanning mirror being a non-rigid body. For example, referring to FIG. 2C, the computer model may determine the different nodes associated with different angular displacements θ with the application of a given angular acceleration \ddot{θ}.

In certain other aspects of step 604, simulation model unit 542 may simulate scanning mirror oscillation for the given angular acceleration \ddot{θ} by computing an angular displacement associated with each of the plurality of nodes, the angular displacement of a node being computed based at least in part on an associated vertical displacement and distance to an axis of rotation of the scanning mirror. For example, referring to FIG. 2C, the angular displacement θ associated with each of the nodes may be computed by the computer model.

In still further aspects of step 604, simulation model unit 542 may simulate scanning mirror oscillation by computing an average angular displacement of the scanning mirror assembly based at least in part on the angular displacement computed for each of the plurality of nodes. For example, referring to FIG. 2C, to simplify computations associated with determining torque as a function of angular displacement θ, the computer model may first compute the average angular displacement θ for all nodes across the entire surface of the scanning mirror 202. For example, the computer model may determine the average angular displacement of all nodes using Equation (6) seen above for the given angular acceleration \ddot{θ}.

In still another aspect of step 604, simulation model unit 542 may simulate scanning mirror oscillation by computing a torque as a function of average angular displacement across a scanning mirror angle associated with the scanning mirror assembly. For example, referring to FIG. 2C, using the determined angular displacements, under the same angular acceleration \ddot{θ}, the resulting torque can be computed for all rotating bodies in the assembly (e.g., scanning mirror 202, gimbal 214, comb drive fingers 206b) using Equation (7) seen above.

In further aspects of step 604, simulation model unit 542 may simulate scanning mirror oscillation by generating a data set that correlates the torque and the angular displacement across the scanning mirror angle associated with the scanning mirror assembly as an output of the computer model. For example, referring to FIG. 3, the angular acceleration \ddot{θ} may be changed incrementally, and the average angular displacement θ may be computed for each of these increments of angular acceleration. The angular accelerations \ddot{θ} may be those associated with different scanning angles. Then the computer model may compute the torque of the entire scanning mirror assembly as a function of the average angular displacement associated with that angular acceleration, and so on until torque as a function of angular displacement for each of the simulated angular accelerations have been computed. The computer model may save the resulting data as a lookup table that correlates torque and angular displacement, an example of which is shown in FIG. 3.

In certain aspects of step 604, simulation model unit 542 may simulate scanning mirror oscillation by performing cubic polynomial curve fitting using the dataset that correlates torque and the angular displacement across the scanning mirror angle of the scanning mirror assembly. In certain aspects, the initial non-linear spring constant is computed based at least in part on the cubic polynomial curve fitting. For example, referring to FIGS. 2E, 2G, and 2I, for a scanning mirror assembly design using the initial set of design parameters, for a given relation between angular displacement and torque for a particular design, the computer model may compute the linear spring constant k₁ and the cubic non-linear spring constant k₃ using cubic polynomial curve fitting, examples of which are depicted in FIGS. 2E, 2G, and 2I. The spring constant ratio r₃ may be computed as r₃=k₃/k₁.

At step 606, the computation unit 544 may determine whether the initial (computed) non-linear spring constant meets a target non-linear spring constant k₃′. Upon determining that the initial non-linear spring constant meets the target non-linear spring constant k₃′, the operations may stop. Otherwise, upon determining that the initial non-linear spring constant does not meet the target non-linear spring constant k₃′, method 600 proceeds to step 608.

At step 608, the design parameter adjustment unit 546 may adjust the set of design parameters for the scanning mirror assembly based on a comparison between the initial non-linear spring constant k₃ and a target non-linear spring constant k₃′. In certain aspects, the initial set of design parameters and the adjusted set of design parameters are associated with a same mirror oscillation frequency and linear spring constant. The adjusted set of design parameters may include at least one structural alteration to the at least one spring such as those illustrated in FIGS. 2E, 2G, 2I, and 2L. For example, the at least one structural alteration to the at least one spring may comprise one or more of a change in size of the at least one spring, a change in number of springs of the at least one spring, a change in spacing between two or more springs of the at least one spring, or a change in angle between the at least one spring and a component of the scanning mirror assembly.

At step 610, the communication interface 502 may output the adjusted set of design parameters 505 including the at least one structural alteration to be implemented on the at least one spring. For example, the change to the shape or dimensions of the at least one spring may be output to a user, e.g., a mirror design engineer.

At step 612, the simulation model unit 542 may simulate second scanning mirror oscillation based on the adjusted set of design parameters 505 using the computer model to compute an adjusted non-linear spring constant associated with at least one spring of the scanning mirror assembly. For example, the simulation model unit 542 may rerun the simulation using the adjusted set of design parameters by performing step 604 above and its associated sub-steps.

In some embodiments, based on the simulations performed in method 600, a frequency response curve 507 can be generated, associated with the various spring constants r₃. For example, for each of ratio r₃, by applying all other design parameters to the computer model and by applying a sinusoidal drive voltage, a frequency response curve (e.g., such as the one illustrated in FIG. 4) can be simulated that covers a frequency range starting from slightly below the natural frequency to well above the natural frequency.

Another aspect of the disclosure is directed to a non-transitory computer-readable medium storing instructions which, when executed, cause one or more processors to perform the methods, as discussed above. The computer-readable medium may include volatile or non-volatile, magnetic, semiconductor-based, tape-based, optical, removable, non-removable, or other types of computer-readable medium or computer-readable storage devices. For example, the computer-readable medium may be the storage device or the memory module having the computer instructions stored thereon, as disclosed. In some embodiments, the computer-readable medium may be a disc or a flash drive having the computer instructions stored thereon.

It will be apparent to those skilled in the art that various modifications and variations can be made to the disclosed system and related methods. Other embodiments will be apparent to those skilled in the art from consideration of the specification and practice of the disclosed system and related methods.

It is intended that the specification and examples be considered as exemplary only, with a true scope being indicated by the following claims and their equivalents.

What is claimed is:

1. A method for designing a scanning mirror assembly for an optical sensing system, comprising:
receiving, by a communication interface, an initial set of design parameters for the scanning mirror assembly;
simulating first scanning mirror oscillation, by at least one processor, based on the initial set of design parameters using a computer model to compute an initial non-linear spring constant associated with at least one spring of the scanning mirror assembly;
adjusting, by the at least one processor, the initial set of design parameters for the scanning mirror assembly based on a comparison between the initial non-linear spring constant and a target non-linear spring constant, the adjusted set of design parameters including at least one structural alteration to the at least one spring; and
outputting, by the at least one processor, the at least one structural alteration to be implemented on the at least one spring,
wherein the initial set of design parameters and the adjusted set of design parameters are associated with a same mirror oscillation frequency and linear spring constant.

2. The method of claim 1, wherein the simulating scanning mirror oscillation based on the initial set of design parameters using the computer model comprises:
determining, by the at least one processor, a plurality of nodes associated with a scanning mirror of the scanning mirror assembly, the scanning mirror being a non-rigid body;
computing, by the at least one processor, an angular displacement associated with each of the plurality of nodes, the angular displacement of a node being computed based at least in part on an associated vertical displacement and distance to an axis of rotation of the scanning mirror; and
computing, by the at least one processor, an average angular displacement of the scanning mirror assembly based at least in part on the angular displacement computed for each of the plurality of nodes.

3. The method of claim 2, wherein the simulating scanning mirror oscillation based on the initial set of design parameters using the computer model comprises:
computing, by the at least one processor, a torque as a function of the average angular displacement across a scanning mirror angle associated with the scanning mirror assembly; and
generating, by the at least one processor, a data set that correlates the torque and the angular displacement across the scanning mirror angle associated with the scanning mirror assembly as an output of the computer model.

4. The method of claim 3, wherein the simulating scanning mirror oscillation based on the initial set of design parameters using the computer model comprises:
performing, by the at least one processor, cubic polynomial curve fitting using the data set that correlates torque and the angular displacement across the scanning mirror angle of the scanning mirror assembly,
wherein the initial non-linear spring constant is computed based at least in part on the cubic polynomial curve fitting.

5. The method of claim 1, further comprising:
simulating second scanning mirror oscillation, by the at least one processor, based on the adjusted set of design parameters using the computer model to compute an adjusted non-linear spring constant associated with at least one spring of the scanning mirror assembly.

6. The method of claim 5, further comprising:
generating, by the at least one processor, a frequency response curve associated with the initial non-linear spring constant and the adjusted non-linear spring constant.

7. The method of claim 1, wherein the at least one structural alteration to the at least one spring comprises one or more of a change in size of the at least one spring, a change in number of springs of the at least one spring, a change in spacing between two or more springs of the at least one spring, or a change in angle between the at least one spring and a component of the scanning mirror assembly.

8. An apparatus for designing a scanning mirror assembly for an optical sensing system, comprising:
a communication interface configured to receive an initial set of design parameters of the scanning mirror assembly;
a memory configured to store a computer model configured to simulate scanning mirror oscillation; and
at least one processor coupled to the memory and configured to:
simulate first scanning mirror oscillation based on the initial set of design parameters using the computer model to compute an initial non-linear spring constant associated with at least one spring of the scanning mirror assembly;
adjust the initial set of design parameters for the scanning mirror assembly based on a comparison between the initial non-linear spring constant and a target non-linear spring constant, the adjusted set of design parameters including at least one structural alteration to the at least one spring; and
output the at least one structural alteration to be implemented on the at least one spring,
wherein the initial set of design parameters and the adjusted set of design parameters are associated with a same mirror oscillation frequency and linear spring constant.

9. The apparatus of claim 8, wherein the at least one processor is configured to simulate the first scanning mirror oscillation by:
determining a plurality of nodes associated with a scanning mirror of the scanning mirror assembly, the scanning mirror being a non-rigid body;
computing an angular displacement associated with each of the plurality of nodes, the angular displacement of a node being computed based at least in part on an associated vertical displacement and distance to an axis of rotation of the scanning mirror; and
computing an average angular displacement of the scanning mirror assembly based at least in part on the angular displacement computed for each of the plurality of nodes.

10. The apparatus of claim 9, wherein the at least one processor is configured to simulate the first scanning mirror oscillation by:
compute a torque as a function of the average angular displacement across a scanning mirror angle associated with the scanning mirror assembly; and
generate a data set that correlates the torque and the angular displacement across the scanning mirror angle associated with the scanning mirror assembly as an output of the computer model.

11. The apparatus of claim 10, wherein the at least one processor is configured to simulate the first scanning mirror oscillation by:
perform cubic polynomial curve fitting using the data set that correlates torque and the angular displacement across the scanning mirror angle of the scanning mirror assembly,
wherein the initial non-linear spring constant is computed based at least in part on the cubic polynomial curve fitting.

12. The apparatus of claim 8, wherein the at least one processor is further configured to:
simulate second scanning mirror oscillation based on the adjusted set of design parameters using the computer model to compute an adjusted non-linear spring constant associated with at least one spring of the scanning mirror assembly.

13. The apparatus of claim 12, wherein the at least one processor is further configured to:
generate a frequency response curve associated with the initial non-linear spring constant and the adjusted non-linear spring constant.

14. The apparatus of claim 8, wherein the at least one structural alteration to the at least one spring comprises one or more of a change in size of the at least one spring, a change in number of springs of the at least one spring, a change in spacing between two or more springs of the at least one spring, or a change in angle between the at least one spring and a component of the scanning mirror assembly.

15. A non-transitory computer-readable medium having stored thereon computer instructions, when executed by at least one processor, configured to perform a design method for a scanning mirror assembly of an optical sensing system, the method comprises
receiving an initial set of design parameters for the scanning mirror assembly;
simulating first scanning mirror oscillation, by at least one processor, based on the initial set of design parameters using a computer model to compute an initial non-linear spring constant associated with at least one spring of the scanning mirror assembly;
adjusting the initial set of design parameters for the scanning mirror assembly based on a comparison between the initial non-linear spring constant and a target non-linear spring constant, the adjusted set of design parameters including at least one structural alteration to the at least one spring; and
outputting the at least one structural alteration to be implemented on the at least one spring,
wherein the initial set of design parameters and the adjusted set of design parameters are associated with a same mirror oscillation frequency and linear spring constant.

16. The non-transitory computer-readable medium of claim 15, wherein the simulating scanning mirror oscillation based on the initial set of design parameters using the computer model comprises:
determining a plurality of nodes associated with a scanning mirror of the scanning mirror assembly, the scanning mirror being a non-rigid body;
computing an angular displacement associated with each of the plurality of nodes, the angular displacement of a node being computed based at least in part on an associated vertical displacement and distance to an axis of rotation of the scanning mirror; and
computing an average angular displacement of the scanning mirror assembly based at least in part on the angular displacement computed for each of the plurality of nodes.

17. The non-transitory computer-readable medium of claim 16, wherein the simulating scanning mirror oscillation based on the initial set of design parameters using the computer model comprises:
computing a torque as a function of average angular displacement across a scanning mirror angle associated with the scanning mirror assembly; and
generating a data set that correlates the torque and the angular displacement across the scanning mirror angle associated with the scanning mirror assembly as an output of the computer model.

18. The non-transitory computer-readable medium of claim 17, wherein the simulating scanning mirror oscillation based on the initial set of design parameters using the computer model comprises:
performing cubic polynomial curve fitting using the data set that correlates torque and the angular displacement across the scanning mirror angle of the scanning mirror assembly,
wherein the initial non-linear spring constant is computed based at least in part on the cubic polynomial curve fitting.

19. The non-transitory computer-readable medium of claim 15, wherein the method further comprises:
simulating second scanning mirror oscillation based on the adjusted set of design parameters using the computer model to compute an adjusted non-linear spring constant associated with at least one spring of the scanning mirror assembly.

20. The non-transitory computer-readable medium of claim 19, wherein the method further comprises:
generating a frequency response curve associated with the initial non-linear spring constant and the adjusted non-linear spring constant.
